(19) United States
(12) Patent Application Publication
(10) Pub. No.: US 2025/0020749 A1
(43) Pub. Date: Jan. 16, 2025

(54) SYSTEM AND METHOD FOR RIGID MOTION CORRECTION IN MAGNETIC RESONANCE IMAGING

(71) Applicants: The General Hospital Corporation, Boston, MA (US); Massachusetts Institute of Technology, Boston, MA (US)

(72) Inventors: Nalini Singh, Cambridge, MA (US); Malte Hoffmann, Somerville, MA (US); Stephen R. Frost, Cambridge, MA (US); Adrian V. Dalca, Reading, MA (US); Bruce R. Fischl, Cambridge, MA (US); Polina Golland, Cambridge, MA (US); Elfar Adalsteinsson, Cambridge, MA (US)

(21) Appl. No.: 18/770,330

(22) Filed: Jul. 11, 2024

Related U.S. Application Data
(60) Provisional application No. 63/513,031, filed on Jul. 11, 2023.

(51) Int. Cl. G01R 33/565; G01R 33/56; G06T 11/00

(52) U.S. Cl. CPC G01R 33/56509; G01R 33/5608; G06T 11/005; G06T 2210/41; G06T 2211/441

(57) ABSTRACT

A system for rigid motion correction for magnetic resonance imaging (MRI) of a subject includes an input for receiving motion corrupted k-space data for the subject acquired using an MRI system, a motion parameter estimation module coupled to the input and configured to estimate motion parameters based on the motion corrupted k-space data, a motion correction neural network coupled to the input and the motion parameter estimation module and configured to generate motion corrected k-space data based on the motion corrupted k-space data and the estimated motion parameters, and a reconstruction module coupled to the motion correction neural network and configured to generate a motion corrected image from the motion corrected k-space data.

### CROSS-REFERENCE TO RELATED APPLICATIONS

This application is based on, claims priority to, and incorporates herein by reference in its entirety U.S. Ser. No. 63/513,031 filed Jul. 11, 2023, and entitled “System For and Method Of Rigid Motion Correction in Accelerated Multi-Shot 2D-Encoded MRI.”

### STATEMENT REGARDING FEDERALLY SPONSORED RESEARCH OR DEVELOPMENT

This invention was made with government support under grant numbers R21EB029641, K99HD101553, 5T32EB1680, P41EB015896, 1R01EB023281, R01EB006758, R21EB018907, R01EB019956, R01EB017337, P41EB03000, 1R01EB032708, P41EB015902, U01HD087211, 1R56AG064027, 5R01AG008122, R01AG016495, 1R01AG070988, RF1AG068261, R01MH123195, R01MH121885, R01NS052585, R21NS072652, R01NS070963, R01NS083534, 5U01NS086625, 5U24NS10059103, R01NS105820, 5U01-MH093765, and U01MH117023 awarded by the National Institutes of Health. The government has certain rights in the invention.

### FIELD

The present disclosure relates generally to magnetic resonance imaging and, more particularly, to system and methods for rigid motion correction for magnetic resonance imaging.

### BACKGROUND

Motion frequently corrupts MRI acquisitions, degrading image quality or necessitating repeated scans. Motion artifacts are a pervasive problem in MRI, leading to misdiagnosis or mischaracterization in, for example, population-level imaging studies. For example, subject motion frequently corrupts brain magnetic resonance imaging (MRI) and obfuscates anatomical interpretation. Prospective motion correction strategies adapt the acquisition in real-time to adjust for measured rigid-body motion. Unfortunately, prospective strategies require altering clinical workflows, prolonging scans, or interfering with standard acquisition parameters. Retrospective strategies correct motion algorithmically after acquisition, with or without additional motion measurements. Retrospective motion correction without additional motion information (e.g., subject head motion measurements) is particularly appealing, because it does not require external hardware or clinical pulse sequence modifications and enables retroactive correction of large, previously collected k-space datasets.

### SUMMARY

In accordance with an embodiment, a system for rigid motion correction for magnetic resonance imaging (MRI) of a subject, the system including an input for receiving motion corrupted k-space data for the subject acquired using an MRI system, a motion parameter estimation module coupled to the input and configured to estimate motion parameters based on the motion corrupted k-space data, a motion correction neural network coupled to the input and the motion parameter estimation module and configured to generate motion corrected k-space data based on the motion corrupted k-space data and the estimated motion parameters, and a reconstruction module coupled to the motion correction neural network and configured to generate a motion corrected image from the motion corrected k-space data.

In accordance with another embodiment, a method for rigid motion correction for magnetic resonance imaging (MRI) of a subject, the method includes receiving motion corrupted k-space data for the subject acquired using an MRI system, generating, using a motion parameter estimation module, estimated motion parameters based on the motion corrupted k-space data, providing the motion corrupted k-space data and the estimated motion parameters to a motion correction neural network, generating, using the motion correction neural network, motion corrected k-space data based on the motion corrupted k-space data and the estimated motion parameters, and generating, using a reconstruction module, a motion corrected image from the motion corrected k-space data.

### BRIEF DESCRIPTION OF THE DRAWINGS

The present disclosure will hereafter be described with reference to the accompanying drawings, wherein like reference numerals denote like elements.

FIG. 1 is a block diagram of an example magnetic resonance imaging (MRI) system in accordance with an embodiment;

FIG. 2 is a block diagram of a system for rigid motion correction for magnetic resonance imaging of a subject in accordance with an embodiment;

FIG. 3 illustrates a method for rigid motion correction for magnetic resonance imaging of a subject in accordance with an embodiment;

FIG. 4 illustrates a method for training a rigid motion correction neural network in accordance with an embodiment; and

FIG. 5 is a block diagram of an example computer system in accordance with an embodiment.

### DETAILED DESCRIPTION

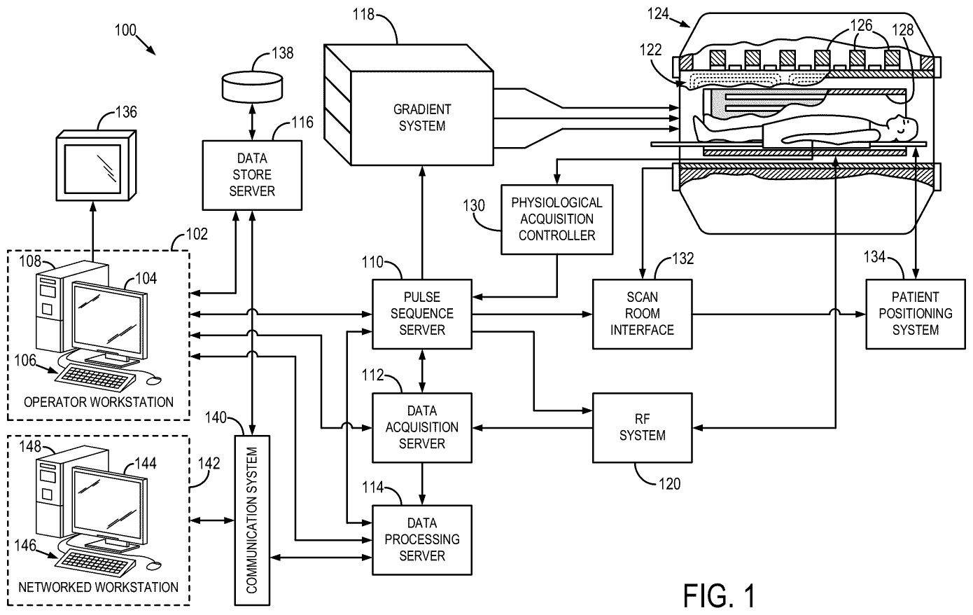

FIG. 1 shows an example of an MRI system 100 that may be used to perform the methods described herein. The MRI system 100 includes an operator workstation 102, which may include a display 104, one or more input devices 106 (e.g., a keyboard and mouse), and a processor 108.

The processor 108 may include a commercially available programmable machine running a commercially available operating system. The operator workstation 102 provides the operator interface that facilitates entering scan parameters (e.g., a scan prescription) into the MRI system 100. The operator workstation 102 may be coupled to different servers, including, for example, a pulse sequence server 110, a data acquisition server 112, a data processing server 114, and a data store server 116. The operator workstation 102 and the servers 110, 112, 114, and 116 may be connected via a communication system 140, which may include any suitable network connection, whether wired, wireless, or a combination of both.

The pulse sequence server 110 functions in response to instructions provided by the operator workstation 102 to operate a gradient system 118 and a radiofrequency (“RF”) system 120. Gradient waveforms for performing a prescribed scan are produced and applied to the gradient system 118, which excites gradient coils in an assembly 122 to produce the magnetic field gradients Gₓ, G_{y}, and G_{z} that are used for spatially encoding magnetic resonance signals. The gradient coil assembly 122 forms part of a magnet assembly 124 that includes a polarizing magnet 126 and a whole-body RF coil 128 and/or a local coil.

RF waveforms are applied by the RF system 120 to the RF coil 128, or a separate local coil (not shown in FIG. 1) to perform the prescribed magnetic resonance pulse sequence. Responsive magnetic resonance signals detected by the RF coil 128, or a separate local coil (e.g., the head coil 129), are received by the RF system 120. The responsive magnetic resonance signals may be amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the prescribed scan and direction from the pulse sequence server 110 to produce RF pulses of the desired frequency, phase, and pulse amplitude waveform. The generated RF pulses may be applied to the whole-body RF coil 128 or to one or more local coils or coil arrays.

The RF system 120 also includes one or more RF receiver channels. Each RF receiver channel includes an RF preamplifier that amplifies the magnetic resonance signal received by the coil 128,129 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

$$M = \sqrt{{I}^{2} + {Q}^{2}} \qquad ( 1 )$$

and the phase of the received magnetic resonance signal may also be determined according to the following relationship:

$$φ = {tan}^{- 1} ( \frac{Q}{I} ) \qquad ( 2 )$$

The pulse sequence server 110 may receive patient data from a physiological acquisition controller 130. By way of example, the physiological acquisition controller 130 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 110 to synchronize, or “gate,” the performance of the scan with the subject's heartbeat or respiration.

The pulse sequence server 110 may also connect to a scan room interface circuit 132 that receives signals from various sensors associated with the condition of the patient and the magnet system. Through the scan room interface circuit 132, a patient positioning system 134 can receive commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, such that no data is lost by data overrun. In some scans, the data acquisition server 112 passes the acquired magnetic resonance data to the data processor server 114. In scans that require information derived from acquired magnetic resonance data to control the further performance of the scan, the data acquisition server 112 may be programmed to produce such information and convey it to the pulse sequence server 110. For example, during pre-scans, magnetic resonance data may be acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also process magnetic resonance signals used to detect the arrival of a contrast agent in a magnetic resonance angiography (“MRA”) scan. For example, the data acquisition server 112 may acquire magnetic resonance data and process it in real-time to produce information that is used to control the scan.

The data processing server 114 receives magnetic resonance data from the data acquisition server 112 and processes it in accordance with instructions downloaded from the operator workstation 102. Such processing may include, for example, reconstructing two-dimensional or three-dimensional images by performing a Fourier transformation of raw k-space data, performing other image reconstruction algorithms (e.g., iterative or back-projection reconstruction algorithms), applying filters to raw k-space data or to reconstructed images, generating functional magnetic resonance images, or calculating motion or flow images.

Images reconstructed by the data processing server 114 are conveyed back to the operator workstation 102 for storage. Real-time images may be stored in a data base memory cache (not shown in FIG. 1), from which they may be output to operator display 104 or a display 136. Batch mode images or selected real time images may be stored in a host database on disc storage 138. When such images have been reconstructed and transferred to storage, the data processing server 114 notifies the data store server 116 on the operator workstation 102. The operator workstation 102 may be used by an operator to archive the images, produce films, or send the images via a network to other facilities.

The MRI system 100 may also include one or more networked workstations 142. By way of example, a networked workstation 142 may include a display 144, one or more input devices 146 (e.g., a keyboard and mouse), and a processor 148. The networked workstation 142 may be located within the same facility as the operator workstation 102, or in a different facility, such as a different healthcare institution or clinic.

The networked workstation 142 may gain remote access to the data processing server 114 or data store server 116 via the communication system 140. Accordingly, multiple networked workstations 142 may have access to the data processing server 114 and the data store server 116. In this manner, magnetic resonance data, reconstructed images, or other data may be exchanged between the data processing server 114 or the data store server 116 and the networked workstations 142, such that the data or images may be remotely processed by a networked workstation 142. This data may be exchanged in any suitable format, such as in accordance with the transmission control protocol (TCP), the internet protocol (IP), or other known or suitable protocols.

The present disclosure describes systems and methods for rigid motion correction for magnetic resonance imaging (MRI) of a subject including within-slice (or intra-slice) rigid motion correction. The disclosed system for rigid motion correction can include a motion-correction neural network that can be configured to generate motion-corrected or motion-free k-space data from motion corrupted k-space data acquired from a subject (e.g., a patient) and estimates of the corresponding motion parameters. A motion-corrected image can be reconstructed from the motion corrected k-space data generated by the motion correction neural network. An input to the motion correction neural network can include k-space data acquired from the subject that can be motion corrupted as a result of rigid motion (e.g., head movement of a subject during a multi-shot brain MRI). The system can also include a motion parameter estimation module configured to generate estimated motion parameters (e.g., rigid motion parameters) based on the motion corrupted k-space data acquired from the subject. The estimated motion parameters can be provided as an input to the motion correction neural network. In some embodiments, a first subnetwork configured to generate reconstruction weights based on the estimated motion parameters, and a second subnetwork (or reconstruction subnetwork) configured to utilize the reconstruction weights generated by the first subnetwork and to generate the motion corrected k-space data from the input motion corrupted k-space data. In some embodiments, the motion parameter estimation module can be configured to optimize the estimated motion parameters based on a data consistency loss. In some embodiments, the data consistency loss computed by the motion parameter estimation module can be used to automatically reject the corrected k-space data generated by the motion correction neural network if the optimization fails (e.g., the data consistency loss is greater than a predetermined percentage (e.g., 5%) of the total signal energy of the motion corrupted k-space data input to the motion correction neural network).

Advantageously, the disclosed system and method for rigid motion correction does not require auxiliary measurements (e.g., head motion of the subject) during the scan (or acquisition). The disclosed systems and method for rigid motion correction provide a deep learning method for retrospective rigid motion correction. As mentioned, in some embodiments, the disclosed systems and methods for rigid motion correction can be used for intra-slice motion correction in a multi-shot acquisition which acquires multiple k-space segments per slice. The disclosed systems and methods for rigid motion correction utilizing a deep learning neural network reliably produce high-quality reconstructions and can successfully remove substantial motion artifacts.

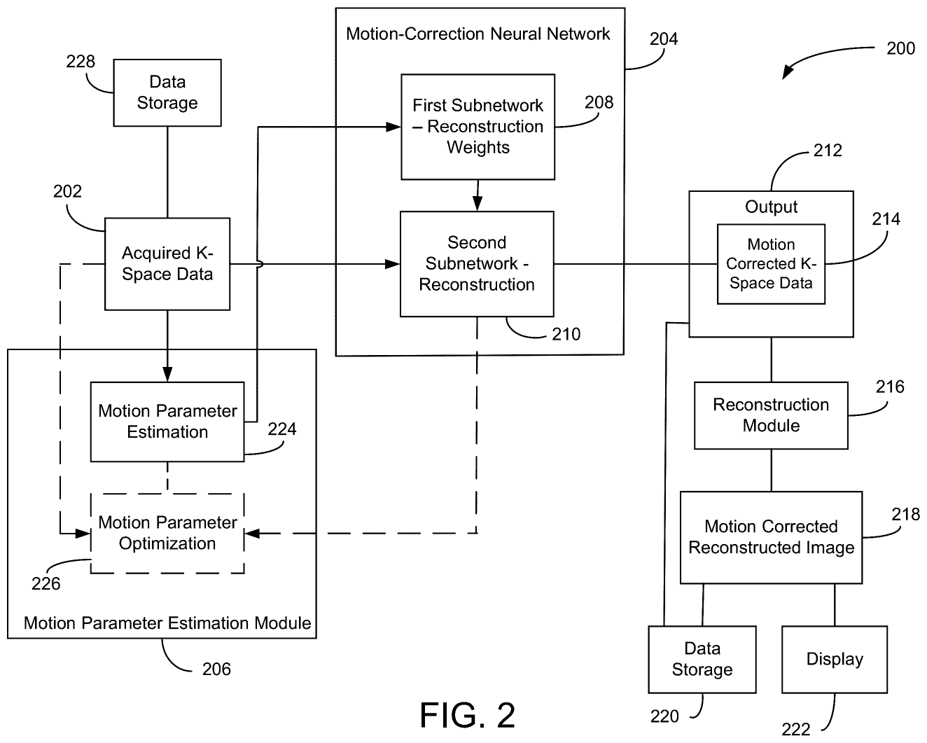

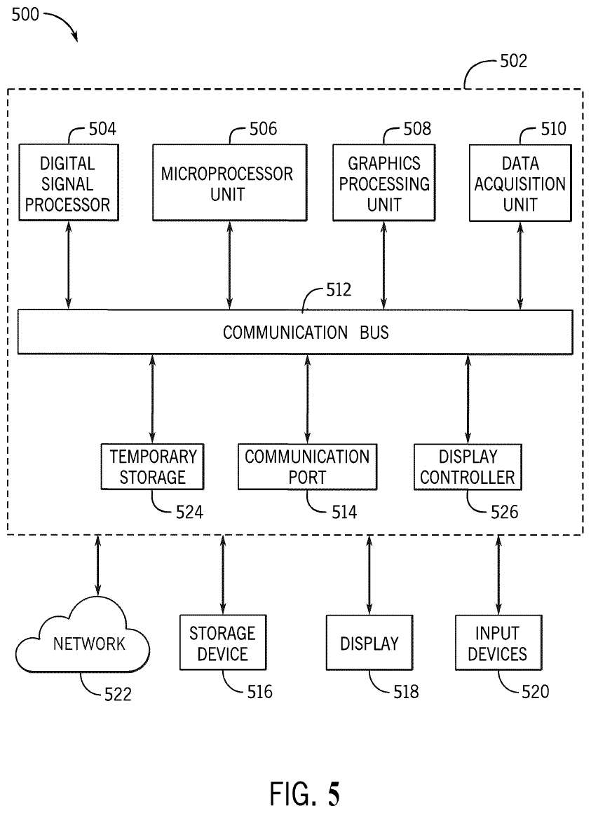

FIG. 2 is a block diagram of a system for rigid motion correction for magnetic resonance imaging of a subject in accordance with an embodiment. The system for rigid motion correction 200 can include an input 202, including motion-corrupted k-space data acquired from a subject, a motion correction neural network 204 (e.g., a deep learning neural network), a motion parameter estimation module 206, an output 212 of the motion correction neural network 204 including amotion corrected k-space data 214, an image reconstruction module 216, a display 222, and data storage 220, 228. The system 200 may be configured to generate (or reconstruct) a motion corrected image 218 of the subject using the motion correction neural network 204. The input k-space data 202 from the subject may be acquired using an MRI system (e.g., MRI system 100 shown in FIG. 1) using known acquisition techniques and protocols. In some embodiments, the k-space data 202 may be acquired from the subject using a multi-shot acquisition technique such as, for example, two dimensional (2D) FLAIR fast spin echo (FSE). The motion corrupted k-space data 202 can include real and imaginary components. In some embodiments, the k-space data 202 may be acquired using a plurality of receive coils. In some embodiments, the acquired k-space data 202 from the subject may be retrieved from data storage (or memory) 228 of system 200, data storage of an MRI system used to acquire the k-space data 202, or data storage of other computer systems (e.g., storage device 516 of computer system 500 shown in FIG. 5). In some embodiments, the k-space data 202 may be acquired in real time from the subject using an MRI system (e.g., MRI system 100 shown in FIG. 1) and the system 200 may be implemented inline with a reconstruction pipeline. For example, k-space data 202 can be acquired from a subject using an MRI acquisition technique or protocol. The acquired k-space data 202 may be stored in, for example, data storage of an MRI system, or data storage of other computer system (e.g., storage device 56 of computer system 500 shown in FIG. 5).

The motion parameter estimation module 206 can be configured to receive the input motion corrupted k-space data 202 and to estimate motion parameters, m, from the input motion corrupted k-space data 202. In some embodiments, the estimated motion parameters can be, for example, rigid per shot motion parameters. In some embodiments, the motion parameter estimation module 206 include a process 224 for motion parameter estimation and an optional motion parameter optimization module 226 (discussed further below). In some embodiments, the motion parameter estimation process can be implemented as a neural network, for example, using three interleaved layers, which combine frequency and image space convolutions. The estimated motion parameters, m, can be provided as inputs to the motion correction neural network 204. In some embodiments, the estimated motion parameters can include, for example, scalars representing x- and y-translations and a rotation for each shot of k-space. The estimated motion parameters can represent the object pose in each of the k-space shots.

As mentioned, the acquired k-space 202 can be motion corrupted. The motion corrupted k-space data 202 from the subject may be provided as an input to the motion correction neural network 204. In some embodiments, the input motion corrupted k-space data 202 can be normalized by dividing by the maximum intensity in the corrupted k-space data 202. In addition, the estimated motion parameters estimated by the motion parameter estimation module 206 can also be provide as an input to the motion correction neural network 204. The motion correction neural network 204 can be trained and configured to generate motion corrected k-space data 214 from the input motion corrupted k-space data 202 and the estimated motion parameters. The motion correction neural network 204 can enable within-slice (or intra-slice) motion correction. In some embodiments the motion correction neural network 204 can be a deep learning neural network that may be implemented using deep learning models or architectures. In some embodiments, the motion correction neural network 204 can include two subnetworks 208, 210. A first subnetwork 208 can be configured to generate weights for the second subnetwork 210 based on the motion parameters input to the first subnetwork 206. In some embodiments, the first subnetwork can be a hypernetwork which is a neural network that can generate weights for another neural network. In some embodiments, the first subnetwork 208 may be implemented using three fully connected layers to output the weights of the second subnetwork 210. The second subnetwork 210 can be configured as a reconstruction subnetwork configured to generate motion corrected k-space data 214 from the motion corrupted k-space data 202 and using the weights generated by the first subnetwork 208. Accordingly, the inputs to the second subnetwork 210 can include the motion corrupted k-space 202 and the weights from the first subnetwork 208. In some embodiments, the second subnetwork 210 can be implemented using six successive interleaved layers combining convolutions in both frequency and image space followed by a single convolution. The output of the second subnetwork (or the reconstruction subnetwork) 210 can include the motion corrected k-space 214. Advantageously, the motion correction neural network 204 architecture can enable the reconstruction strategy to vary with different motion parameters. The motion correction neural network 204 including the first 208 and second 210 subnetworks can provide a mapping from the estimated motion parameters to a motion corrected reconstruction. In addition, the motion correction neural network 204 can provide flexible prediction of the second (or reconstruction) subnetwork 210 specific to the motion parameters.

The output 212 of the motion correction neural network 204 including the motion corrected k-space data 214 may be stored in data storage 220. In some embodiments, the output motion corrected k-space data 214 can be normalized by dividing by the maximum intensity in the corrupted k-space data 202. The motion corrected k-space data 214 may then be reconstructed into a motion corrected image 218 using, for example, the image reconstruction module 216 and known reconstruction methods for MR images. For example, in some embodiments, the reconstruction module 216 may be configured to reconstruct the motion corrected image 218 from the motion corrected k-space data 214 using an inverse Fourier transform and root-sum-of-square coil combination. The motion corrected image 218 generated by the reconstruction module 216 may be stored in, for example, data storage of 220 of the system 200, data storage of an MRI system (e.g., MRI system 100 shown in FIG. 1), or data storage of other computer systems (e.g., storage device 516 of computer system 500 shown in FIG. 5). The motion corrected image 218 may also be displayed to a user or operator on a display 222.

As mentioned above, in some embodiments, the motion parameter estimation module 206 may also include an optional motion parameter optimization module 226 that can be configured to optimize the estimated motion parameters. In some embodiments, the motion parameter optimization module 226 can use an optimization-based approach to estimate motion parameters, m, by minimizing a differentiable loss. For example, the motion parameter optimization module 226 may be configured to minimize a data consistency loss between the motion parameters, the motion corrected k-space data generated by the motion correction neural network 204 given those motion parameters, and the acquired k-space data 202. The data consistency loss can estimate the L2 discrepancy between the input corrupted k-space data 202 and the k-space data that would have been acquired had the reconstructed image (x) been subject to motion as described by the estimated motion parameters (m). In some embodiments, the data consistency loss term may be given by:

$$\vert y - A ( m ) ( x ) {\vert}^{2} \qquad ( 3 )$$

where A is a forward imaging operator, m is the motion parameters, x is the underlying 2D image to be recovered, and y is the acquired k-space data 202. the forward imaging operator A can be a function of the motion parameters, m, and, in some embodiments, may be given by Equation 6 below. The motion parameter optimization module 226 can be configured to receive the motion corrupted k-space data 202 and the output motion correct k-space data from the second subnetwork 210. The motion parameter optimization module 226 can be used to enforce data consistency between the estimated output motion corrected k-space data 214 and the acquired motion corrupted k-space data 202. In some embodiments, the optimization of the motion parameters using a data consistency loss function can be given by:

$$\hat{m} = {argmin}_{m} ‖ A ( m ) f ( y , m ; {θ}_{h}^{*} ) - y {‖}^{2} \qquad ( 4 )$$

where A is a forward imaging operator, m is the motion parameters, f represents the motion correction neural network 204 and the underlying 2D image to be recovered, θₕ* represents the weights of the second subnetwork 208, and y is the acquired k-space data 202. Advantageously, the optimization is over only the motion parameters which simplifies the optimization.

In some embodiments, the loss (e.g., data consistency loss) of the motion parameter optimization module 226 can be monitored during the optimization to identify failure cases where the reconstruction of motion corrected k-space data 214 (and the reconstruction) are of poor quality. Accordingly, monitoring the, for example, data consistency loss, can provide information about how well the motion correction neural network 204 is performing. In one example, when the, for example, data consistency loss, is high relative to the total signal energy of the acquired k-space data 202, even after optimization, the reconstruction (or motion corrected k-space data 214) can be discarded. In some embodiments, the data consistency loss can be compared to a predetermined threshold, for example, the system 200 can be configured to automatically reject poor reconstructions indicated by a data consistency loss greater than a predetermined percentage (e.g., 5%) of the total signal energy of the motion corrupted k-space data 202.

In some embodiments, the motion correction neural network 204 may be trained using a process that utilizes simulated motion corrupted k-space data as training data. In some embodiments, the simulated motion corrupted training k-space data can be derived from previously-acquired, existing motion-free k-space data using known motion parameters. Each training sample can include, for example, a simulated set of corrupted k-space data, motion parameters, and corrected k-space data. In some embodiments, the simulated motion corrupted k-space data for training can be generated by selecting a ransom shot at which motion occurs and sampling horizontal and vertical translation parameters mₕ, mᵥ and sampling rotation parameter m_{Θ}. In some embodiments, the simulated trained data may be generating using an MRI forward model that describes the MRI imaging process and may be given by:

$${y}_{i} = {A}_{i} x + ϵ \qquad ( 5 )$$

where Aᵢ is a forward imaging operator for the i^{th} coil, x is the underling 2D image to be recovered, yᵢ are the acquired MRI measurements (e.g., k-space data) from the i^{th} coil element, and ∈ is Rician noise. In the presence of motion, the forward operator Aᵢ is a function of motion parameters m and may be given by:

$${A}_{i} ( m ) = {\sum }_{s} {U}_{s} F {C}_{i} {M}_{s} ( m ) \qquad ( 6 )$$

where Aᵢ(m) is the forward imaging operator for the i^{th} coil, U_{S} encodes the undersampling pattern for shot s, F is the 2D Fourier transform, Cᵢ denotes a diagonal matrix which encodes the coil sensitivity profile of the i^{th} coil, and Mₛ(m) is a motion matrix encoding in-plane rigid translation and rotation during shot s.

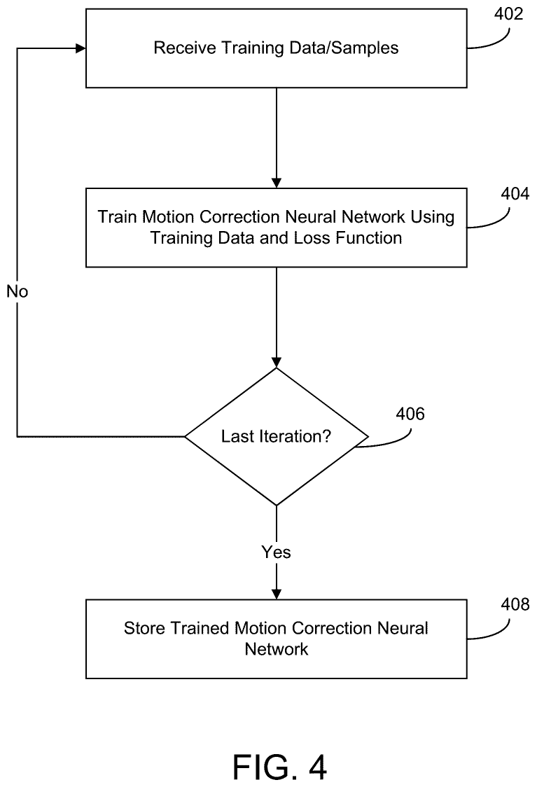

In some embodiments, the motion correction neural network 204 can advantageously be trained using a differentiable image quality loss function such as, for example, a structural similarity image metric (SSIM). An embodiment of a training process for the motion correction neural network 204 is described below with respect to FIG. 4. In some embodiments, a similar process to that shown in FIG. 4 can be used for the optimization of the estimated motion parameters described above

In some embodiments, the motion correction neural network 204, the motion parameter estimation module 206, and the reconstruction module 216 may be implemented on one or more processors (or processor devices) of a computer system such as, for example, any general purpose computer system or device, such as a personal computer, workstation, cellular phone, smartphone, laptop, tablet, or the like. As such, the computer system may include any suitable hardware and components designed or capable of carrying out a variety of processing and control tasks, including, for example, steps for implementing the motion correction neural network 204, implementing the motion parameter estimation module 206, implementing the reconstruction module 216, and receiving k-space data 202 of a subject. For example, the computer system may include a programmable processor or combination of programmable processors, such as central processing units (CPUs), graphics processing units (GPUs), and the like. In some implementations, the one or more processors of the computer system may be configured to execute instructions stored in a non-transitory computer readable-media. In this regard, the computer system may be any device or system designed to integrate a variety of software, hardware, capabilities and functionalities. Alternatively, and by way of particular configurations and programming, the computer system may be a special-purpose system or device. For instance, such special-purpose system or device may include one or more dedicated processing units or modules that may be configured (e.g., hardwired, or pre-programmed) to carry out steps, in accordance with aspects of the present disclosure.

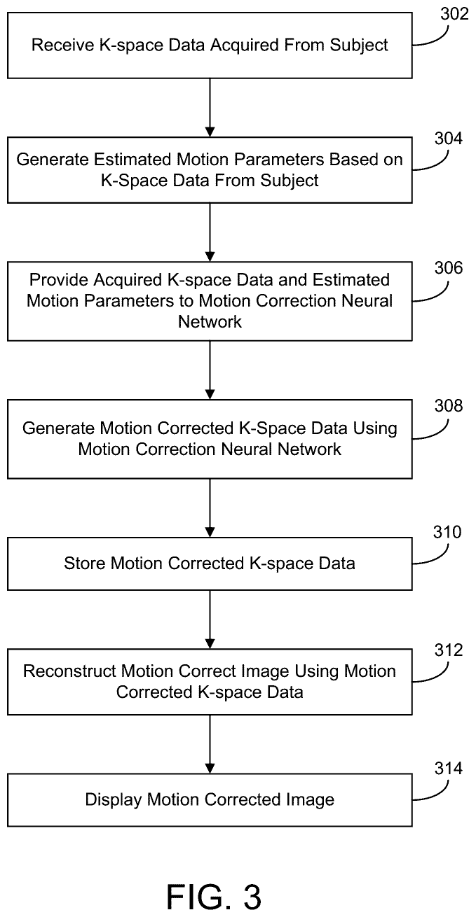

FIG. 3 illustrates a method for rigid motion correction for magnetic resonance imaging of a subject in accordance with an embodiment. The process illustrated in FIG. 3 is described below as being carried out by the system 200 for rigid motion correction for magnetic resonance imaging as illustrated in FIG. 2. However, in some examples, the process of FIG. 3 may be implemented by another system. Although the blocks of the process are illustrated in a particular order, in some embodiments, one or more blocks may be executed in a different order than illustrated in FIG. 3 or may be bypassed.

At block 302, k-space data, e.g., motion corrupted k-space data, acquired from a subject may be received. The k-space data 202 may be acquired using an MRI system (e.g., MRI system 100 shown in FIG. 1) using known acquisition techniques and protocols. As mentioned, in some embodiments, the k-space data 202 may be acquired from the subject using a multi-shot acquisition technique such as, for example, two dimensional (2D) FLAIR fast spin echo (FSE). The motion corrupted k-space data 202 can include real and imaginary components. In some embodiments, the input motion corrupted k-space data 202 can be normalized by dividing by the maximum intensity in the corrupted k-space data 202. In some embodiments, the acquired k-space data 202 from the subject may be retrieved from data storage (or memory) 226 of system 200, data storage of an MRI system used to acquire the k-space data 202, or data storage of other computer systems (e.g., storage device 516 of computer system 500 shown in FIG. 5). The motion corrupted k-space data 202 may be retrieved from data storage (or memory) 226 of system 200, data storage of the MRI system used to acquire the k-space data 202, or data storage of other computer systems (e.g., storage device 516 of computer system 500 shown in FIG. 5). At block 304, estimated motion parameters may be generated, for example, using a motion parameter estimation module 206. As mentioned above, the motion parameters (m) (e.g., rigid per shot motion parameters) can be generated based on the input motion corrupted k-space data 202. In some embodiments, the estimated motion parameters can be optimized using, for example, a motion parameter optimization module 226 as described above. For example, the optimization process may be performed by minimizing data consistency loss between the motion parameters, the motion corrected k-space data generated by the motion correction neural network 204 given those motion parameters, and the acquired k-space data 202.

At block 306, the motion corrupted k-space data 202 and the estimated motion parameters may be provided as an input to a motion correction neural network 204. The motion correction neural network 204 may be a deep learning neural network and implemented using deep learning models or architectures. At block 308, the motion correction neural network 204 may be used to generate motion corrected k-space data 214 from the input motion corrupted k-space data 202 and the estimated motion parameters. In some embodiments, the motion correction neural network 204 can enable within-slice (or intra-slice) motion correction. As mentioned, in some embodiments, the motion correction neural network 204 can include two subnetworks, a first subnetwork 208, and a second subnetwork 210. The first subnetwork 208 can be configured to generate weights for the second subnetwork 210 based on the estimated motion parameters generated by the motion parameter estimation module 206, and the second subnetwork 210 can be configured as a reconstruction subnetwork configured to generate motion corrected k-space data 214 from the motion corrupted k-space data 202 and using the weights generated by the first subnetwork.

In some embodiments, when the motion parameters are optimized as mentioned above, an optional monitoring process may be performed (e.g., using the motion parameter optimization module 226) to monitor the output 212, for example, the reconstruction quality of the motion corrected k-space data and the motion corrected image 218. For example, a loss (e.g., data consistency loss) used for motion parameter optimization can be monitored during the optimization to identify failure cases where the reconstruction of motion corrected k-space data 214 (and the reconstruction) are of poor quality. Accordingly, monitoring the, for example, data consistency loss can provide information about how well the motion correction neural network 204 is performing. In one example, when the, for example, data consistency loss is high relative to the total signal energy of the acquired k-space data 202, even after optimization, the reconstruction (or motion corrected k-space data 214) can be discarded. In some embodiments, the data consistency loss can be compared to a predetermined threshold, for example, the system 200 can be configured to automatically reject poor reconstructions indicated by a data consistency loss greater than a predetermined percentage (e.g., 5%) of the total signal energy of the motion corrupted k-space data 202.

At block 310, the motion corrected k-space data 214 may be stored in data storage 220. At block 312, a motion corrected image 218 may be reconstructed from the motion corrected k-space data 214 using, for example, the image reconstruction module 216 and known reconstruction methods for MR images. For example, in some embodiments, the motion corrected image 218 may be reconstructed from the motion corrected k-space data 214 using an inverse Fourier transform and root-sum-of-square coil combination. In some embodiments, the motion corrected image 218 may be stored in data storage 220. At block 314, the motion corrected image 218 may be displayed on a display 222 (e.g., a display of an MRI system (e.g., MIR system 100 shown in FIG. 1), display 518 of computer system 500 shown in FIG. 5).

As mentioned, the motion correction neural network 204 (shown in FIG. 2) may be trained to generate motion corrected k-space data 214. FIG. 4 illustrates a method for training a rigid motion correction neural network in accordance with an embodiment. Although the blocks of the process are illustrated in FIG. 4 in a particular order, in some embodiments, one or more blocks may be executed in a different order than illustrated in FIG. 4 or may be bypassed.

At block 402, training data or samples may be received. As mentioned, the training data can include simulated motion corrupted k-space data. In some embodiments, the simulated motion corrupted training k-space data can be derived from previously-acquired, existing motion-free k-space data using known motion parameters. Each training sample can include, for example, a simulated set of corrupted k-space data, motion parameters, and corrected k-space data. The training data may be retrieved from data storage (or memory), for example, data storage 228 of system 200 shown in FIG. 2, or data storage of other computer systems (e.g., storage device 516 of computer system 500 shown in FIG. 5).

At block 404, a motion correction neural network 202 may be trained for generating motion corrected k-space data from motion corrupted k-space data using the training data and a loss function. In some embodiments, the loss function can be a differentiable image quality loss function such as, for example, a structural similarity image metric (SSIM). At block 406, it is determined if the last or final iteration for the current training has been reached. In some embodiments, the motion correction neural network 204 can be trained for a predetermined number of iterations. If the last iteration has not been reached, the process returns to block 402 and the motion correction neural network may then be trained in this next training iteration using the training data/samples. If, at block 406, the last iteration has been reached, at block 408, the trained motion correction neural network can be stored in data storage (e.g., data storage of a computer system such as storage device 516 of computer system 500 shown in FIG. 5).

FIG. 5 is a block diagram of an example computer system in accordance with an embodiment. Computer system 500 may be used to implement the systems and methods described herein. In some embodiments, the computer system 500 may be a workstation, a notebook computer, a tablet device, a mobile device, a multimedia device, a network server, a mainframe, one or more controllers, one or more microcontrollers, or any other general-purpose or application-specific computing device. The computer system 500 may operate autonomously or semi-autonomously, or may read executable software instructions from the memory or storage device 516 or a computer-readable medium (e.g., a hard drive, a CD-ROM, flash memory), or may receive instructions via the input device 520 from a user, or any other source logically connected to a computer or device, such as another networked computer or server. Thus, in some embodiments, the computer system 500 can also include any suitable device for reading computer-readable storage media.

Data, such as data acquired with an imaging system (e.g., a magnetic resonance imaging (MRI) system) may be provided to the computer system 500 from a data storage device 516, and these data are received in a processing unit 502. In some embodiment, the processing unit 502 includes one or more processors. For example, the processing unit 502 may include one or more of a digital signal processor (DSP) 504, a microprocessor unit (MPU) 506, and a graphics processing unit (GPU) 508. The processing unit 502 also includes a data acquisition unit 510 that is configured to electronically receive data to be processed. The DSP 504, MPU 506, GPU 508, and data acquisition unit 510 are all coupled to a communication bus 512. The communication bus 512 may be, for example, a group of wires, or a hardware used for switching data between the peripherals or between any components in the processing unit 502.

The processing unit 502 may also include a communication port 514 in electronic communication with other devices, which may include a storage device 516, a display 518, and one or more input devices 520. Examples of an input device 520 include, but are not limited to, a keyboard, a mouse, and a touch screen through which a user can provide an input. The storage device 516 may be configured to store data, which may include data such as, for example, k-space data, training data, motion parameters, motion corrected k-space data, motion corrected reconstructed images, etc. whether these data are provided to, or processed by, the processing unit 502. The display 518 may be used to display images and other information, such as magnetic resonance images, patient health data, and so on.

The processing unit 502 can also be in electronic communication with a network 522 to transmit and receive data and other information. The communication port 514 can also be coupled to the processing unit 502 through a switched central resource, for example the communication bus 512. The processing unit can also include temporary storage 524 and a display controller 526. The temporary storage 524 is configured to store temporary information. For example, the temporary storage 524 can be a random access memory.

Computer-executable instructions for rigid motion correction for magnetic resonance imaging of a subject according to the above-described methods may be stored on a form of computer readable media. Computer readable media includes volatile and nonvolatile, removable, and non-removable media implemented in any method or technology for storage of information such as computer readable instructions, data structures, program modules or other data. Computer readable media includes, but is not limited to, random access memory (RAM), read-only memory (ROM), electrically erasable programmable ROM (EEPROM), flash memory or other memory technology, compact disk ROM (CD-ROM), digital volatile disks (DVD) or other optical storage, magnetic cassettes, magnetic tape, magnetic disk storage or other magnetic storage devices, or any other medium which can be used to store the desired instructions and which may be accessed by a system (e.g., a computer), including by internet or other computer network form of access

The present technology has been described in terms of one or more preferred embodiments, and it should be appreciated that many equivalents, alternatives, variations, and modifications, aside from those expressly stated, are possible and within the scope of the invention.

1. A system for rigid motion correction for magnetic resonance imaging (MRI) of a subject, the system comprising:
an input for receiving motion corrupted k-space data for the subject acquired using an MRI system;
a motion parameter estimation module coupled to the input and configured to estimate motion parameters based on the motion corrupted k-space data;
a motion correction neural network coupled to the input and the motion parameter estimation module, and configured to generate motion corrected k-space data based on the motion corrupted k-space data and the estimated motion parameters; and
a reconstruction module coupled to the motion correction neural network and configured to generate a motion corrected image from the motion corrected k-space data.

2. The system according to claim 1, wherein the motion correction neural network comprises:
a first subnetwork configured to receive the estimated motion parameters and generate a set of weights based on the estimated motion parameters;
a second subnetwork coupled to the input and the second subnetwork and configured to include the weights from the first subnetwork and to generate the motion corrected k-space data from the motion corrupted k-space data.

3. The system according to claim 1, wherein the motion parameter estimation module comprises a plurality of interleaved layers combining frequency and image space convolutions.

4. The system according to claim 1, wherein the motion parameter estimation module is further configured to optimize the estimated motion parameters using a data consistency loss and based on the motion corrupted k-space data and the motion corrected k-space data.

5. The system according to claim 1, wherein the motion corrupted k-space data is acquired using a multi-shot acquisition.

6. The system according to claim 1, wherein the motion corrupted k-space data and the motion corrected k-space data are normalized based on a maximum intensity of the motion corrupted k-space data.

7. The system according to claim 1, further comprising a display coupled to the reconstruction module and configured to display the motion corrected image.

8. The system according to claim 1, wherein the motion correction neural network is a deep learning neural network.

9. The system according to claim 2, wherein the first subnetwork is a hypernetwork.

10. The system according to claim 2, wherein the second subnetwork comprises a plurality of successive interleaved layers combining convolutions in both frequency and image space followed by a single convolution.

11. A method for rigid motion correction for magnetic resonance imaging (MRI) of a subject. the method comprising:
receiving motion corrupted k-space data for the subject acquired using an MRI system;
generating, using a motion parameter estimation module, estimated motion parameters based on the motion corrupted k-space data;
providing the motion corrupted k-space data and the estimated motion parameters to a motion correction neural network;
generating, using the motion correction neural network, motion corrected k-space data based on the motion corrupted k-space data and the estimated motion parameters; and
generating, using a reconstruction module, a motion corrected image from the motion corrected k-space data.

12. The method according to claim 11, further comprising optimizing, using the motion parameter estimation module, the estimated motion parameters using a data consistency loss and based on the motion corrupted k-space data and the motion corrected k-space data.

13. The method according to claim 11, wherein the motion corrupted k-space data is acquired using a multi-shot acquisition.

14. The method according to claim 11, wherein the motion corrupted k-space data and the motion corrected k-space data are normalized based on a maximum intensity of the motion corrupted k-space data.

15. The method according to claim 11, further comprising displaying the motion corrected image.

16. The method according to claim 11, wherein the motion correction neural network is a deep learning neural network.

17. The method according to claim 11, wherein generating, using the motion correction neural network, motion corrected k-space data based on the motion corrupted k-space data and the estimated motion parameters further comprises generating a set of weights based on the estimated motion parameters.

18. The method according to claim 17, wherein generating, using the motion correction neural network, motion corrected k-space data based on the motion corrupted k-space data and the estimated motion parameters further comprises generating the motion corrected k-space data from the motion corrupted k-space data based on the set of weights.
